(19) United States
(12) Patent Application Publication
(10) Pub. No.: US 2024/0153901 A1
(43) Pub. Date: May 9, 2024

(54) Methods of Integrated Chip of Ultra-Fine Pitch Bonding and Resulting Structures

(71) Applicant: Taiwan Semiconductor Manufacturing Co., Ltd., Hsinchu (TW)

(72) Inventors: Yu-Hung Lin, Taichung City (TW); Han-Jong Chia, Hsinchu (TW); Wei-Ming Wang, Taichung City (TW); Kuo-Chung Yee, Taoyuan City (TW); Chen Chen, New Taipei City (TW); Shih-Peng Tai, Xinpu Township (TW)

(21) Appl. No.: 18/151,714

(22) Filed: Jan. 9, 2023

Related U.S. Application Data
(60) Provisional application No. 63/382,325, filed on Nov. 4, 2022.

(51) Int. Cl. H01L 23/00

(52) U.S. Cl. CPC H01L 24/08; H01L 24/05; H01L 24/80; H01L 24/13; H01L 2224/05553; H01L 2224/05555; H01L 2224/05556; H01L 2224/05571; H01L 2224/05624; H01L 2224/05647; H01L 2224/05649; H01L 2224/05657; H01L 2224/05666; H01L 2224/0568; H01L 2224/05684; H01L 2224/0603; H01L 2224/06181; H01L 2224/06505; H01L 2224/08123; H01L 2224/08147; H01L 2224/13147; H01L 2224/80357; H01L 2224/80379; H01L 2224/80896; H01L 2924/04642; H01L 2924/0544; H01L 2924/059

(57) ABSTRACT

A first and second semiconductor device are bonded together using a bonding contact pad embedded within a bonding dielectric layer of the first semiconductor device and at least one bonding via embedded within a bonding dielectric layer of the second semiconductor device. The bonding contact pad extends a first dimension in a first direction perpendicular to the major surface of the first semiconductor device and a second dimension in a second direction parallel to the plane of the first semiconductor wafer, the second dimension being at least twice the first dimension. The bonding via extends a third dimension in the first direction and a fourth dimension in the second direction, the third dimension being at least twice the first dimension. The bonding contact pad and bonding via may be at least partially embedded in respective bonding dielectric layers in respective topmost dielectric layers of respective stacked interconnect layers.

### PRIORITY CLAIM AND CROSS-REFERENCE

This application claims the benefit of U.S. Provisional Application No. 63/382,325, filed on Nov. 4, 2022, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

Stacked semiconductor devices have emerged as an effective technique for further reducing the physical size of a semiconductor device. In a stacked semiconductor device, active circuits such as logic and memory circuits are fabricated on different semiconductor wafers. Two or more semiconductor wafers may be bonded together through suitable bonding techniques to further reduce the form factor of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate cross-sectional views of a first semiconductor device at intermediate stages of manufacture in accordance with some embodiments.

FIG. 2 illustrates a cross-sectional view of a second semiconductor device at an intermediate stage of manufacture in accordance with some embodiments.

FIG. 3 illustrates a cross-sectional view of the first semiconductor device and the second semiconductor device bonded together in accordance with some embodiments.

FIGS. 4A through 4C illustrate in greater detail cross-sectional views of different embodiment bonding pads and bonding vias.

FIGS. 5A and 5B, 6A and 6B, and 7A through 7D illustrate in top-down view different embodiment bonding pad and bonding via combinations.

FIGS. 8A through 8C illustrate cross-sectional views of different embodiments of a first and second semiconductor device bonded together.

FIGS. 9A through 9F illustrate in greater detail cross-sectional views of still additional embodiment bonding pads and bonding vias.

FIG. 10 schematically illustrates dimensions of an exemplary bonding pad and an exemplary bonding via.

FIG. 11 is a flow of an embodiment manufacturing process.

FIG. 12 schematically illustrates a packaged device including the results of additional back-end processing.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

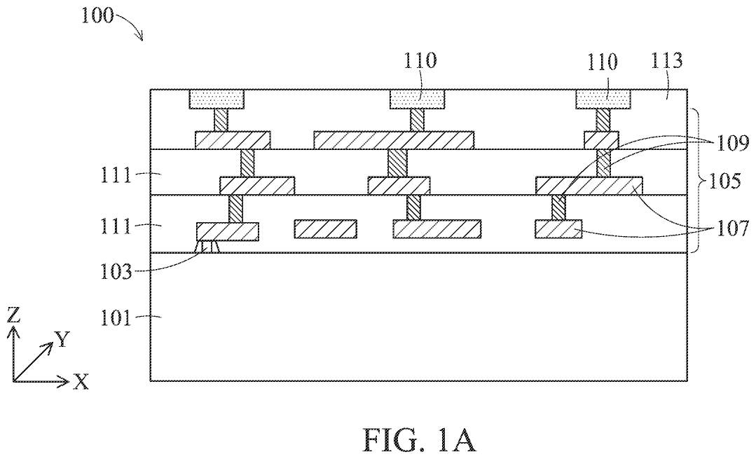

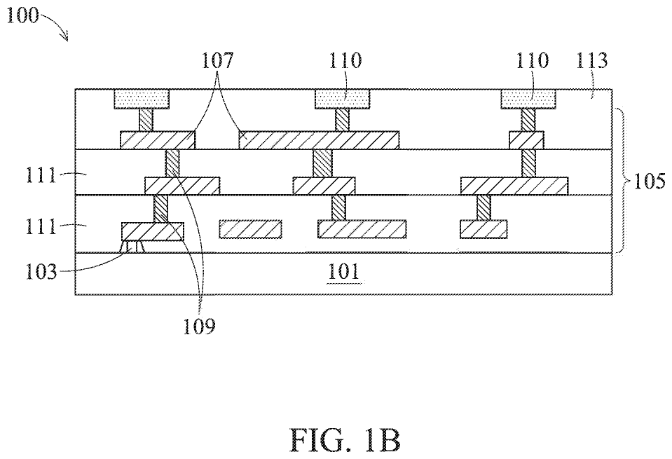

FIG. 1A illustrates a side view of a first exemplary semiconductor device 100, which includes a substrate 101. For clarity, only a small portion of substrate 101, is shown. The first semiconductor device 100 may be a die or a package component in some embodiments. The substrate 101 may be a bulk silicon substrate although other semiconductor materials including group III, group IV, and group V elements may also be used. Active devices 103, such as transistors, may be formed in and/or on the substrate 101.

An interconnect structure 105 is formed over the substrate 101. In some embodiments, the interconnect structure 105 may include at least one dielectric layer 111, such as a dielectric layer 111 formed of silicon oxides, silicon oxy-nitrides, silicon carbides, low-k dielectric materials having k values, for example, lower than about 4.0, and the like. In some embodiments, the dielectric layers of the interconnect structure 105 may be made of, for example, silicon oxide, SiCOH, and the like. The interconnect structure 105 includes metal lines 107 for interconnecting various active devices 103 and further include vias 109 for interconnecting metal lines that are located in different layers of interconnect structure 105, which are formed in the respective dielectric layers 111. As used herein, and consistent with common usage in the art, the term lines will be used to refer to conductive structures that reside within one layer of interconnect structure 5 and generally run in a an X or Y direction, i.e. parallel to the major surface of substrate 101, and the term vias will be used to refer to a conductive structure that extends between and electrically interconnects different layers of lines within interconnect structure, generally running in the Z direction, or perpendicular to the major surface of substrate 101. While only 3 layers of lines is illustrated in exemplary interconnect structure 105 of FIG. 1, one skilled in the art will recognize that many such layers, perhaps eight or more, could be employed in a practical application. The metal lines 107 and vias 109 may be formed of copper or copper alloys, although they can also be formed of other metals. The metal lines and vias may be formed by etching openings in the dielectric layers, filling the openings with a conductive material, and performing a planarization (such as a chemical mechanical polishing, or CMP) to level top surfaces of the metal lines and vias with top surfaces of the dielectric layers. Typically, a metal line 107 and an underlying via 109 are using a dual damascene process in the relevant dielectric layer 111 is first patterned to have an opening corresponding to metal line 107 and then patterned a second time to have an opening corresponding to via 109, after which the openings are filled with, e.g., copper (a so-called trench-first dual damascene process), or else the relevant dielectric layer 111 is first patterned to have an opening corresponding to via 109 and then patterned a second time to have an opening corresponding to metal line 107 after which both openings are filled with, e.g., copper (a so-called via-first dual damascene process).

As FIG. 1A further illustrates interconnect structure 105 includes a topmost layer that includes metal lines 107 in the topmost layer and further includes contact pads 110 also formed within, or at least partially within topmost dielectric layer 111. As shown, topmost vias 109 formed within topmost dielectric layer 111 electrically connect topmost metal lines 107 to respective contact pads 110. As above, topmost metal lines 107 and topmost vias 109 may be formed using a trench-first or a via-first dual damascene process.

Although not limiting, contact pads 110 may be formed of the same or similar material as metal lines 107, such as copper or a copper alloy (or other metals such as, by way of example, and not by way of exhaustion or limitation, other metals could include molybdenum, manganese, titanium, tungsten, aluminum, cobalt, and alloys of same). In some embodiments, contact pads can be formed also using a damascene process, although a deposition process such as electroplating electro-less plating and the like is also within the contemplated scope of the present disclosure. Regardless of the process by which contact pads 110 are formed, it is desirable in most embodiments that contact pads 110 have respective top surfaces that are substantially planar with the top surface of the topmost dielectric layer as the topmost surfaces will serve as bonding surfaces during a wafer-to-wafer bonding process that will be further described in subsequent paragraphs. In some embodiments, however, some or all of the respective topmost surfaces of contact pads 110 may be slightly below the top surface of the topmost dielectric layer, provided that the distance between the respective top surfaces of contact pads 110 and the top surface of the topmost dielectric layer is sufficiently small that the gap can be filled either by thermal expansion of the respective contacts pads 110, mechanical deformation of the topmost dielectric layer, or a combination of both.

FIG. 1B illustrates the semiconductor device 100 is FIG. 1A after an optional wafer thinning process has been performed, in which process the thickness of substrate 101 is substantially reduced. In some contemplated embodiments, the thickness of substrate 101 is reduced from perhaps 750 μm to around 30 μm, or perhaps 50 μm, or perhaps 100 μm, depending upon the application for which semiconductor device 100 is to be employed. As known in the art, such thinning can be accomplished through a backside grinding process, a backside etch process, or the like. As will be described below, semiconductor device 100 is bonded to another semiconductor device in subsequent processing. In some embodiments, semiconductor device is subjected to thinning after it is bonded to another semiconductor device, rather than before, and in yet other embodiments, no thinning of semiconductor device 100 is performed. Because the only difference between the device illustrated in FIG. 1A and the device illustrated in FIG. 1B is the optional backside thinning step, both FIGS. 1A and 1B might be generally referred to in subsequent paragraphs as FIG. 1, unless the context indicates or requires otherwise.

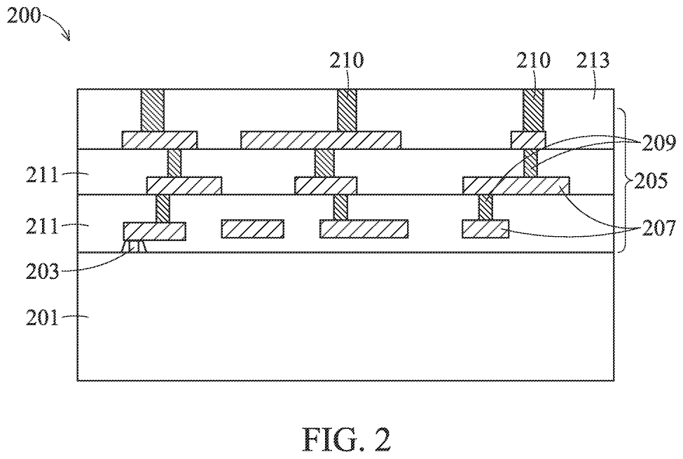

FIG. 2 illustrates a side view of a second exemplary semiconductor device 200, which likewise includes a substrate 201. For clarity, only a small portion of substrate 201, is shown. The second semiconductor device 200 may likewise be a die or a package component, in some embodiments. The substrate 201 may be a similar substrate as substrate 101 (FIG. 1), or a completely different type of substrate. While not a necessarily limiting factor, as a matter of guidance, the thermal expansion characteristics of substrate 201 and semiconductor device 200 generally 100 is preferably matched, or at least compatible with, those of substrate 101 and/or semiconductor device 100. Active devices 203, such as transistors, may be formed in and/or on the substrate 201. In other embodiments, however, such as when semiconductor device 200 is an interposer or similar passive structure (i.e., a structure that has only electrical interconnection and/or passive devices such as capacitors, inductors, resistors, and the like), then no such active devices 203 are provided with semiconductor device 200.

As with semiconductor device 100, semiconductor device 200 also includes an interconnect structure 205, which in the illustrated embodiment has three layers of metal lines 207 embedded within respective dielectric layers 211. Metal lines 207 interconnect various active devices 203, if present, or other passive devices (not shown) if present and may be made of similar materials as metal lines 107 of FIG. 1 (although metal lines 207 of different materials formed using different processes relative to metal lines 107 is within the contemplated scope of this embodiment). Similarly, dielectric layers 211 may be similar to the materials of dielectric layers 111, but this again is not a limiting factor or a requirement of the present disclosure. FIG. 2 also discloses vias 209 electrically interconnecting different layers of metal lines 207. As above, a distinction between metal lines 207 and vias 209 is that metal lines generally extend in the X-Y plane and electrically interconnect different features within a layer, whereas vias extend in the Z direction and electrically interconnect features within different layers of interconnect structure 105 (as well as features that are not part of interconnect structure 205). While only three layers of lines 207 are illustrated in exemplary interconnect structure 205 of FIG. 2, one skilled in the art will recognize that only one or many such layers could be employed in a practical application.

As FIG. 2 further illustrates interconnect structure 205 also includes a topmost layer that includes metal line 207 in the topmost layer. The topmost layer has embedded, or at least partially embedded therein contact vias 210. Note that, because there are not metal lines above contact vias 210, these contact vias 210 can be formed using a single damascene process, which reduced the complexity and cost of manufacturing.

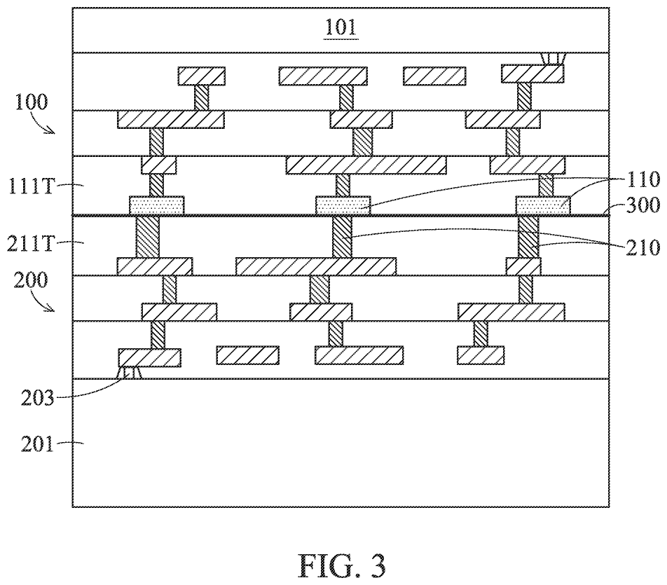

A significant distinction between semiconductor device 100 (FIG. 1) and semiconductor device 200 of FIG. 2 is the absence of contact pads 110 in the device illustrated in FIG. 2. In fact, the inventors of the present disclosure have recognized that several advantages may be obtained in embodiments described herein wherein a semiconductor device used in a wafer-to-wafer bonding process is formed to have contact vias, such as contact vias 210 illustrated in FIG. 2, form mating and bonding with contact pads, such as contact pads 110 shown in FIG. 1. One such embodiment is shown in FIG. 3 which illustrates a package device including semiconductor 100 and semiconductor 200 after they have been bonded together. Note particularly that in the illustrated scheme there are no corresponding contacts pads in semiconductor device 200 to which contact pads 110 of semiconductor device 100 align and bond. Rather, as shown, contact pads 110 of semiconductor device 100 align with and bond directly to contact vias 210 of semiconductor device 200. More specifically, as shown in FIG. 3, semiconductor device 100 is inverted so that the top surface of its topmost dielectric layer 110T is facing downwards (in the illustrated orientation) and likewise the top surface of respective contact pads 110 are also facing downwards (in the illustrated orientation). In this way, contact pads 110 can be aligned to and brought into direct contact with contact vias 210 of semiconductor device 200 (in some embodiments, contact pads 110, or contact vias 210, or both contact pads 110 and contact vias 210 are slightly recessed below the topmost surface of the dielectric layer 111/211 in which they are formed, in which cases the respective contact pads/contact vias would be aligned but would not necessarily be in contact until further processing [e.g., thermal treatment[has been performed). Similarly, topmost dielectric layer 111T of semiconductor device 100 and topmost dielectric layer 211T of semiconductor device 200 are also brought into alignment and contact and these dielectric layers bond together to form a bond interface 300 therebetween.

As addressed above, the use of contact vias 210 being directly bonded to contact pads 110 simplifies the manufacturing/bonding process (e.g., single damascene processing versus dual damascene processing, a more flexible overlay window, and the like), and hence lowers the costs of the resulting structure. Additional advantageous features will be apparent in light of the following description of further embodiments.

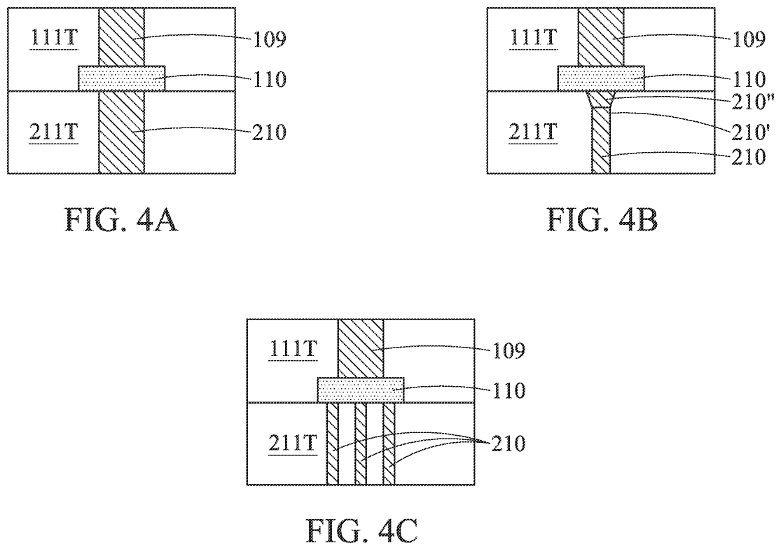

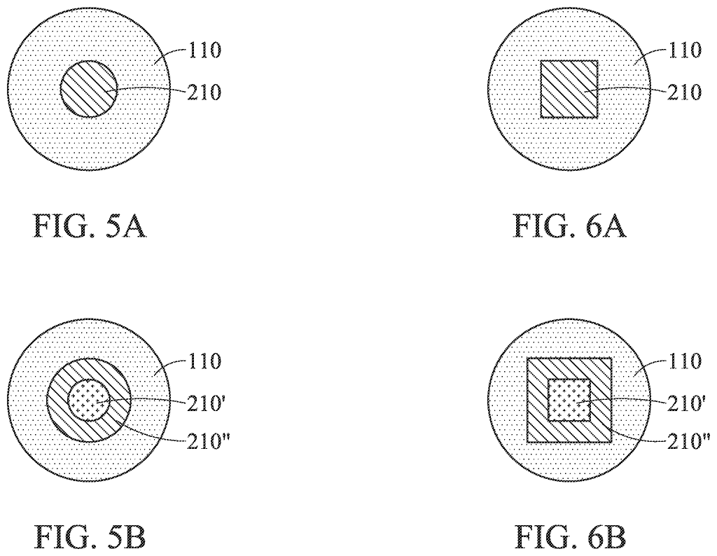

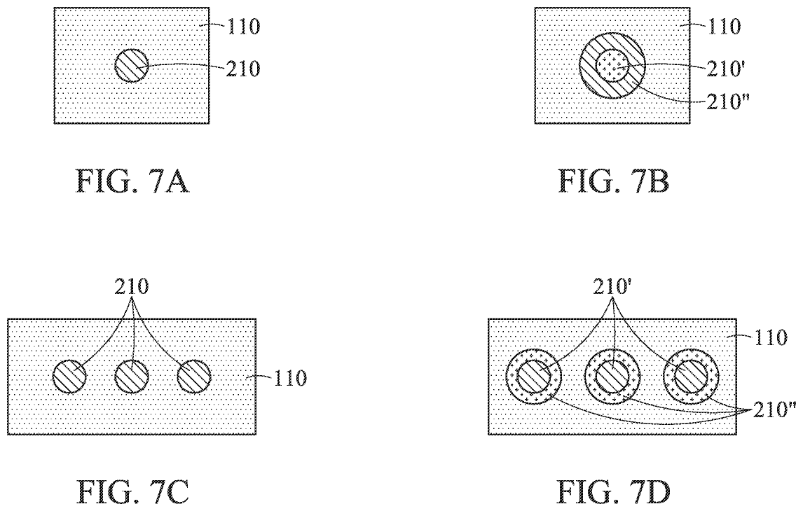

Continuing then, with FIGS. 4A through 4C, these figures illustrate in cross-sectional view alternative embodiments of an exemplary contact pad 110 bonded to an exemplary contact via 210. In FIG. 4A, contact via 210 is configured as a single conductive via having substantially vertical and parallel sidewalls. FIG. 5A illustrates in top-down view the configuration shown in FIG. 4A. As shown, the overall surface area of contact via 210 is less than the surface area of contact pad 110—while not a limiting factor, in some embodiments the surface area of contact via 210 could be as low as 25% the surface area of contact pad 110. FIG. 6A illustrates yet another embodiment in top-down view wherein the relationship of surface area of contact pad 110 to surface area of contact via 210 is similar as shown for FIG. 5A, but wherein contact via 210 has a rectangular shape when viewed in top-down view. By contrast, in the embodiment of FIG. 7A, contact pad 110 has a rectangular shape in the top-down view, whereas contact via 210 has a circular or round shape in top-down view. Once again, the surface area of contact 210 relative to contact pad 110 provides for a lenient alignment window in this embodiment. While not illustrated, embodiments wherein both contact via 210 and contact pad 110 both have a rectangular shape are also within the contemplated scope of this disclosure.

Turning now to FIGS. 4B, 5B, 6B, and 7B, these figures illustrate various embodiments wherein contact via 210 has a tapered profile, as best illustrated in the cross-sectional view of FIG. 4B. One skilled in the art will recognize that various processes could be employed to form a tapered profile such as shown in FIG. 4B. As but one example, a photomask layer, such as photoresist (not shown) could be formed on topmost dielectric layer 211T (prior to bonding to semiconductor device 100) and this photoresist layer could be patterned to have an opening therein with a tapered profile—which tapered profile would be transferred to the underlying dielectric layer using, e.g., an appropriate etching process. With such a tapered profile, contact via 210 has a fist cross-sectional size at point 210′ where the taper begins and a second larger cross-sectional size at point 210″ at the topmost surface of contact via 210, the point where contact via 210 bonds to contact pad 110. This configuration provides a larger surface area for bonding and a lower resistance relative to the configuration illustrated in, e.g., FIGS. 4A and 5A. Having a large surface area contact pad relative to the surface area of the contact via provides for a more lenient alignment window when contact via 210 is aligned to contact pad 110.

FIG. 5B illustrates the configuration of FIG. 4B in top-down view. Although contact via 210 would not be visible in the top-down view, as it would be obscured by contact pad 110, the features are illustrated herein for the sake of showing the relative size and surface are of the features, including contact pad 110 and contact via 210 at point 210′ and 210″ which are described abo e. Similarly, configurations having a tapered rectangular contact via 210 are shown in top-down view in FIG. 6B and a tapered contact via 210 with a rectangular contact pad 110 in FIG. 7B.

Returning now to FIG. 4C, in this embodiment multiple contact vias 210 are bonded to contact pad 110. This configuration is illustrated in cross-sectional view by FIG. 4C, and FIG. 7C illustrates same in top-down view. While circular contact vias 210 are shown bonded to a rectangular contact pad 110, one skilled in the art will recognize any combination of circular and/or rectangular (or any other shape) contact vias 210 with any combination of circular and/or rectangular (or any other shape) contact pads 110 and still stay within the contemplated scope of this disclosure. Additionally, and as illustrated in FIG. 7D, combinations of the configurations of FIGS. 4A, 4B, and 4C are also contemplated, such as an embodiment wherein multiple tapered contact vias 210 are bonded to each (or select ones of) contact pad 110.

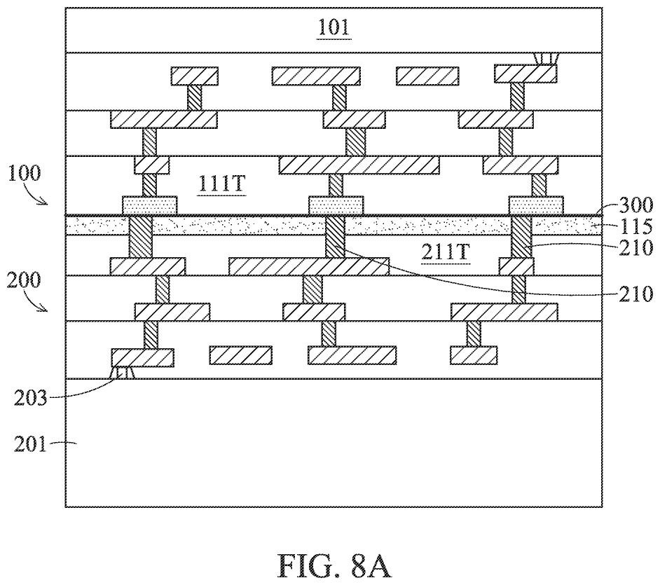

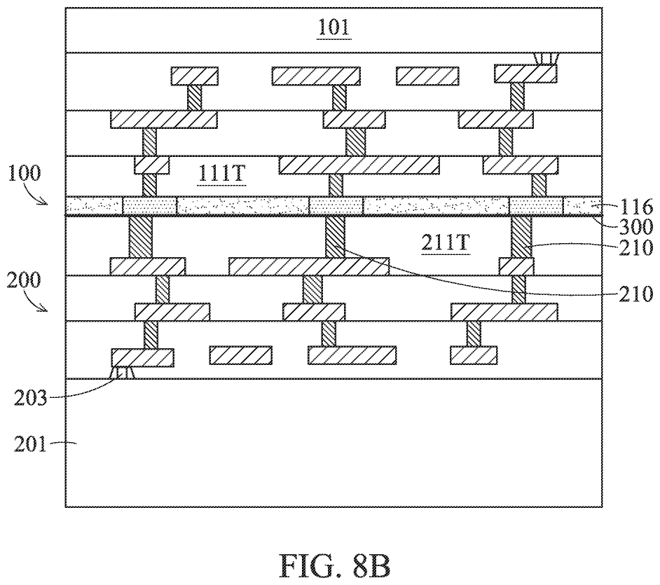

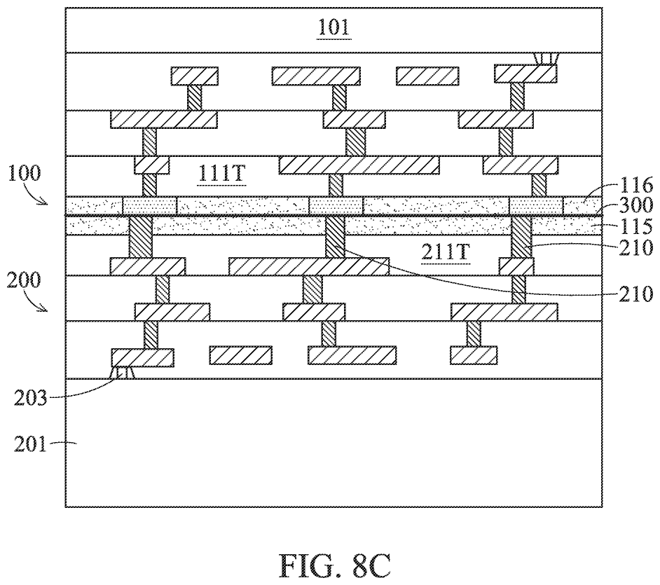

Yet additional embodiments are illustrated in FIGS. 8A, 8B, and 8C. Starting with FIG. 8A, in this embodiment semiconductor device 200 includes a bonding dielectric layer 115 in which contact vias 210 are formed or at least partially formed, which bonding dielectric layer 115 bonds to topmost dielectric layer 111T of semiconductor device 100. Bonding dielectric layer 115 could be a silicon oxide layer, a silicon oxy-nitride layer, a silicon carbide layer, or the like, as examples. Similarly, in FIG. 8B, a bonding dielectric layer 116 is formed on semiconductor device 100 and this bonding dielectric layer 116 bonds to topmost dielectric layer 211T of semiconductor device 200 in this illustrated embodiment. In yet another embodiment, bonding dielectric layer 115 is formed as the topmost surface for semiconductor device 200 and bonding dielectric layer 116 is formed as the topmost surface for semiconductor device 100 and bonding dielectric layers 115 and 116 are brought into contact and bonded together in order to bond semiconductor device 100 to semiconductor device 200, as shown in FIG. 8C.

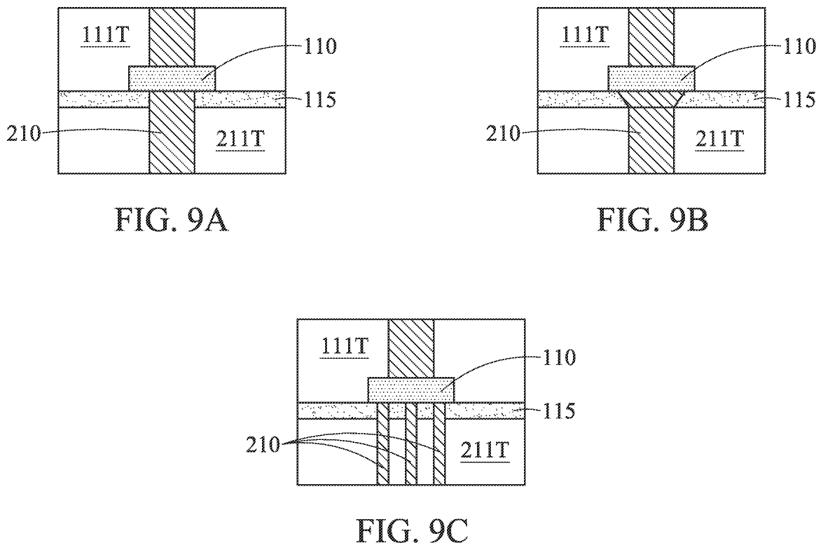

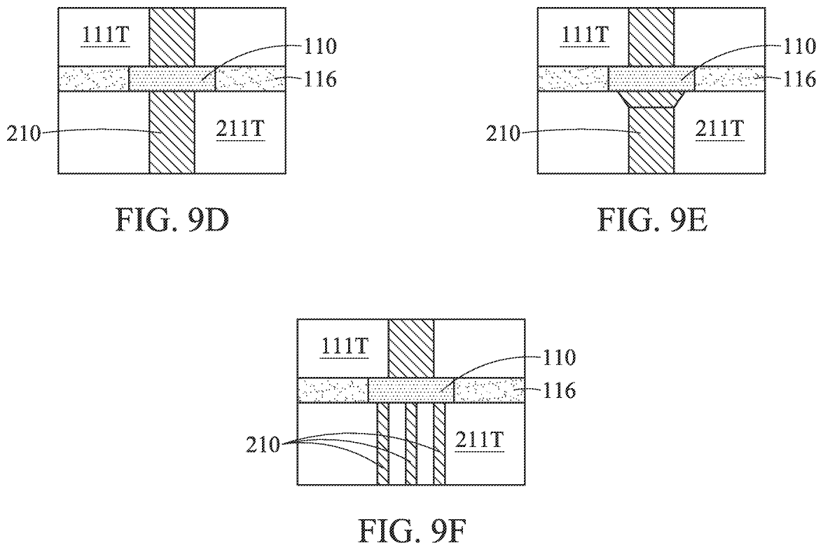

FIGS. 9A, 9B, and 9C illustrate in cross-sectional view the contact vias 210 illustrated in FIGS. 4A, 4B, and 4C, respectively, formed in or at least partially within bonding dielectric layer 115 and bonded to contact pads 110 which are formed in or at least partially formed in topmost dielectric layer 111T. Likewise, FIGS. 9D, 9E, and 9F illustrate in cross-section view contact pads 110 formed in or at least partially formed in bonding dielectric layer 116 and bonded to respective contact vias 210.

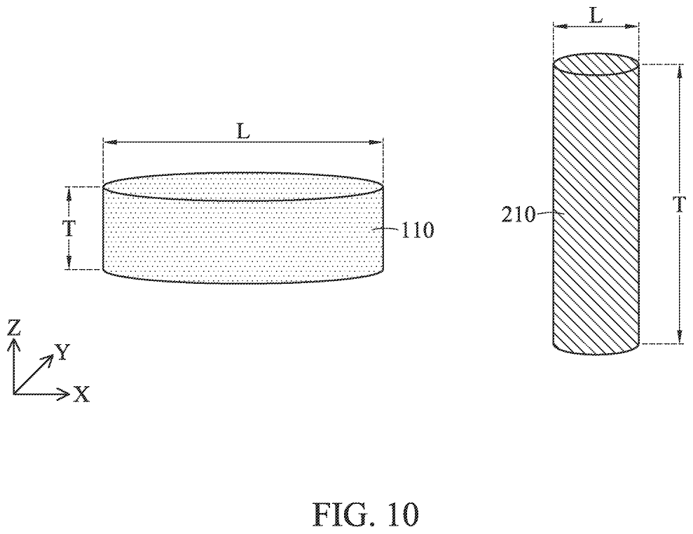

As addressed above, advantages can be obtained through the use of bonding vias being bonded to bonding contact pads. These advantages flow, in art, from the distinction between a contact via and a contact pad. Taking the embodiment of FIG. 4A as an example, and as discussed somewhat above exemplary contact via 210 is a conductive via—meaning it is primarily oriented in a vertical direction (“vertical being used herein to describe the orientation that is perpendicular to plan of substrate 201), whereas exemplary contact pad 210 is horizontally oriented (i.e. extending primarily in a direction that is parallel to the plane of substrate 201). These distinctions are schematically illustrated by FIG. 10, showing an exemplary bonding via 210 which that a vertical dimension “T” extending in the Z direction and a horizontal dimension L extending in the X-Y plane. Note that, as an artifact of the function of contact via 210 (vertically interconnecting features in vertically stacked layers or vertically stacked orientation), the vertical “T” dimension is appreciably greater than the horizontal L dimension for contact via 210. By contrast, and as also schematically illustrated in FIG. 10, exemplary contact pad 110 has a horizontal dimension “L” extending in the X-Y plane that is appreciably greater than its vertical “T” dimension that extends in the Z direction. As an example, for a contact pad 110, the ratio of “L” to “T” will typically be in the range of several hundred, perhaps 1,000:1. By contrast, contact via 210 will have an opposite relationship, with a ratio of “T” to “L” being in the range of around 1,000:1 being typical, ranging as low as around 3:1 or 2:1 in the outer boundaries of this range. Because of the variation in layer thicknesses and minimum feature sizes, the respective “T” to “L” ratios for contact pad 110 and contact via 210 can vary widely from application to application. The relative relationship between these two ratios is hence a more reliable guide. In most instances, contact via 210 will have a “T” dimension in the Z direction that is at least two times the “T” dimension of the contact pad 110, and more preferably at least twenty times the “T” dimension of contact pad 110. Likewise, as a useful guide, the “L” dimension of contact pad 110 should be at least 1.1 times the “L” dimension of contact via 210, and more preferably at least 1.2 times.

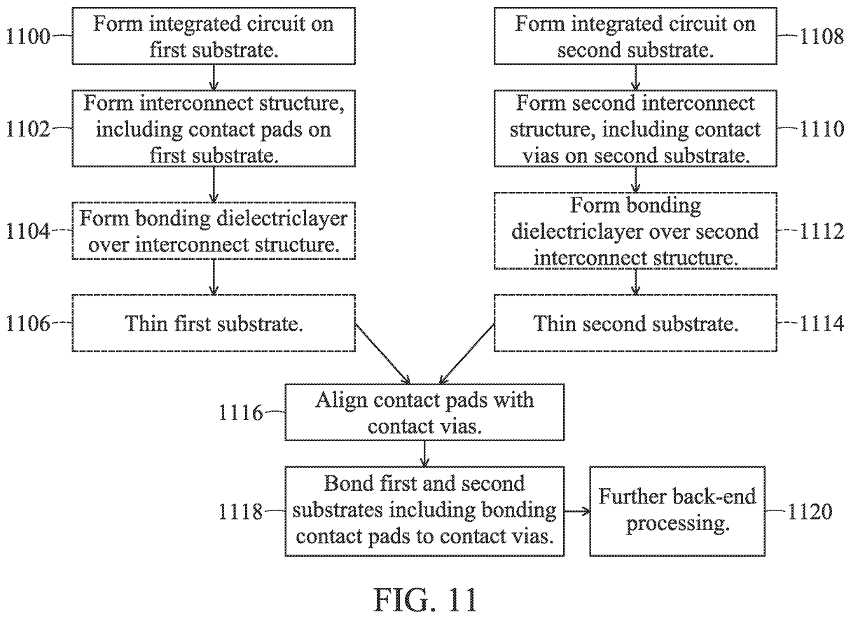

A flow chart for an exemplary manufacturing process embodiment is illustrated in FIG. 11. Beginning with step 1100, a first integrated circuit is formed on a first substrate. Next, an interconnect structure, including contact pads is formed, as illustrated by step 1102. Simultaneously, previously, or subsequently, a second integrated circuit may optionally (as indicated by the dotted line box 1108) be formed on a second substrate and a second interconnect structure, excluding bonding contact but including bonding vias, may be formed on the second substrate (step 1110). Optionally, a bonding dielectric layer may be formed over the first interconnect structure of the first semiconductor device, as illustrated by optional step (dotted line box) 1104. Alternatively or additionally, a bonding dielectric layer may be formed over the second interconnect structure as indicated by dotted line box 1112. Optionally, the first substrate may be thinned down from its backside, as indicated at optional step 1106. Alternatively or additionally, the second substrate may optionally be thinned down from its backside as indicated by step 1114. At step 1116, the contact pads of the first interconnect structure and the contact vias of the second interconnect structure are aligned to another. Then, the first and second substrates are bonded together, including bonding together the contact pads and the contact vias. Finally, further back-end processing such as additional back-side thinning, electrically connecting to through-substrate vias, forming electrical connectors, and the like is performed as indicated by step 1120.

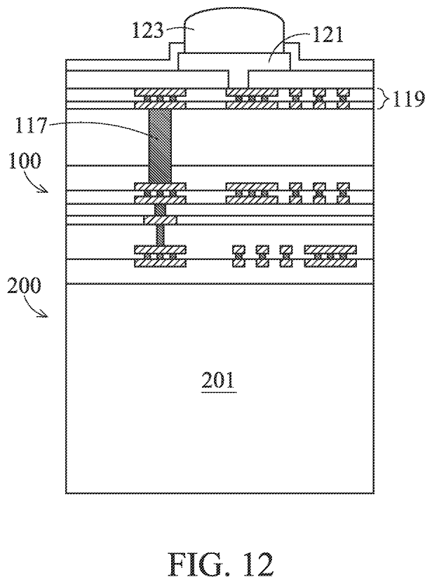

An example of further back-end processing, step 1120, is illustrated in FIG. 12, which shows semiconductor device 100 bonded to semiconductor device 200, and further show through-substrate via 117 extending through substrate 101 (one skilled in the art will recognize that through-substrate via 117 is typically formed, at least in part simultaneously with the formation of interconnect structure 105 (see step 1102 of FIG. 11). Also illustrated in FIG. 12 is a back-side redistribution layer (RDL) 119 that electrically connects through-substrate via 117 (and other electrical components of semiconductor 100 as well) to aluminum back-side pad 121 and external connector 123. One skilled in the art will recognize that external connector 123 could be a solder bump, a copper micro-bump or copper pillar, a controlled collapse chip connection, or the like.

The above-described embodiments are intended to be exemplary and are not intended to be nor should they construed to be limiting in terms of scope, exhaustion, or limitation. One skilled in the will recognize, for instance, that the above-described embodiments and configurations are not mutually exclusive (unless such mutual exclusivity is self-evident form the context of the description) and hence the various elements of the above-described embodiments can be combined together in various and additional ways beyond those ways specifically illustrated herein, which various and additional ways are within the contemplated scope of this disclosure and the claim appended hereto. For instance, one skilled in the art will recognize that the bonding via can be formed on the top semiconductor device 200 rather than the bottom semiconductor device 100 as illustrated. Likewise, either or both or neither of the semiconductor wafers could be subjected to back-side thinning, either before or after the bonding process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of forming a semiconductor package, the method comprising:
forming first active components on a first semiconductor wafer,
forming over the first active components, using a dual damascene process, a first interconnect structure including first stacked layers of metal lines embedded within respective dielectric layers and further forming, using a dual damascene process, a conductive via and a bonding contact pad, the bonding contact pad being embedded at least partially in a first bonding dielectric layer, the conductive via electrically connecting the bonding contact pad and a top metal line of the first stacked layers,
forming on a second semiconductor wafer a second interconnect structure comprising second stacked layers of second metal lines embedded in respective second dielectric layers and further forming, using a single damascene process, a bonding via at least partially embedded in a second bonding dielectric layer;
aligning the bonding via and the bonding contact pad;
bringing the first bonding dielectric layer into contact with the second bonding dielectric layer;
bonding the first bonding dielectric layer to the second bonding dielectric layer; and
bonding the bonding via to the bonding contact pad.

2. The method of claim 1, wherein the top metal line of the first stacked layers is embedded within the first bonding dielectric layer.

3. The method of claim 1, wherein the top metal line of the first stacked layers is embedded within an interconnect structure dielectric layer and further wherein the first bonding dielectric layer is deposited on the interconnect structure dielectric layer.

4. The method of claim 1, wherein the bonding via has a first dimension in a direction perpendicular to the major plane of the first semiconductor wafer, the bonding contact pad has a second dimension in the direction perpendicular to the major plane of the first semiconductor wafer, and wherein a ratio of the first dimension to the second dimension is at least 2:1.

5. The method of claim 1, wherein the bonding via has a first dimension in a direction perpendicular to the major plane of the first semiconductor wafer, the bonding contact pad has a second dimension in the direction perpendicular to the major plane of the first semiconductor wafer, and wherein a ratio of the first dimension to the second dimension is at least 20:1.

6. The method of claim 1, wherein the bonding via has a first dimension in a direction perpendicular to the major plane of the first semiconductor wafer, the bonding contact pad has a second dimension in the direction perpendicular to the major plane of the first semiconductor wafer, and wherein a ratio of the first dimension to the second dimension is in a range of from about 2:1 to about 20:1.

7. The method of claim 1, further including at least one of backside thinning the first semiconductor wafer, backside thinning the second semiconductor wafer, and backside thinning both the first and the second semiconductor wafer.

8. The method of claim 1, further comprising forming on the second semiconductor wafer second active components.

9. The method of claim 1, wherein the bonding contact pad is bonded to the bonding via simultaneously with bonding the first bonding dielectric layer to the second bonding dielectric layer.

10. A method of forming a semiconductor package, the method comprising:
forming on a first semiconductor wafer a bonding contact pad embedded within a first bonding dielectric layer, and an underlying via, the bonding contact pad extending a first dimension in a first direction perpendicular to the first semiconductor wafer and extending a second dimension in a second direction parallel to the plane of the first semiconductor wafer, wherein the second dimension is at least twice the first dimension;
planarizing the first bonding dielectric layer, the bonding contact pad, or both, so that a topmost surface of the bonding contact pad is substantially planar with a topmost surface of the first bonding dielectric layer;
forming on a second semiconductor wafer a second bonding dielectric layer having embedded therein a bonding via, the bonding via extending a third dimension in the first direction and extending a fourth dimension in the second direction, wherein the third dimension is at least twice the first dimension;
aligning the bonding contact pad and the bonding via; and
bonding the bonding contact pad to the bonding via.

11. The method of claim 10, further comprising bonding the first bonding dielectric layer to the second bonding dielectric layer.

12. The method of claim 10 wherein the bonding contact pad and the underlying via are formed together in a dual damascene process and further wherein the bonding via is formed in a single damascene process.

13. The method of claim 10 wherein a ratio of the third dimension to the first dimension is at least 2:1.

14. The method of claim 10 wherein a ratio of the third dimension to the first dimension is at least 20:1.

15. The method of claim 10 wherein a ratio of the second dimension to the fourth dimension is at least 1:1.

16. The method of claim 10 wherein the underlying via is also embedded within the first bonding dielectric layer.

17. The method of claim 10 further comprising tapering upper sidewalls of the bonding via to taper outwards from a centerline of the bonding via.

18. The method of claim 10 further comprising aligning a plurality of bonding vias to the bonding contact pad and bonding the plurality of bonding vias to the bonding contact pad.

19. A device comprising:
a first semiconductor chip having formed thereon first active components,
a first interconnect structure overlying the first active components, the first interconnect structure including a conductive via and a bonding contact pad, the bonding contact pad being embedded at least partially in a first bonding dielectric layer and having a first length in a direction parallel to the major plane of the first semiconductor chip that exceeds a second length in a direction perpendicular to the major plane of the first semiconductor chip;
a second semiconductor chip having formed thereon a second interconnect structure comprising stacked layers of second metal lines embedded in respective second dielectric layers and including a bonding conductive via at least partially embedded in a second bonding dielectric layer, the bonding via having a third length in the direction perpendicular to the major plane of the first semiconductor chip that exceeds a fourth length in a direction parallel to the major plane of the first semiconductor chip;
a major surface of the bonding contact pad being bonded to a major surface of the bonding via; and
a major surface of the first bonding dielectric layer being bonded to a major surface of the second bonding dielectric layer.

20. The device of claim 19 wherein a ratio of the third length to the fourth length exceeds 2:1.
